(19) United States
(12) Patent Application Publication
(10) Pub. No.: US 2013/0168705 A1
(43) Pub. Date: Jul. 4, 2013

(54) SOLID-STATE LIGHT-EMITTING DEVICE AND SOLID-STATE LIGHT-EMITTING PACKAGE THEREOF

(71) Applicant: SHENG PEI LIN, TAICHUNG CITY (TW)

(72) Inventor: SHENG PEI LIN, TAICHUNG CITY (TW)

(73) Assignee: LEXTAR ELECTRONICS CORP., HSINCHU (TW)

(21) Appl. No.: 13/539,571

(22) Filed: Jul. 2, 2012

(30) Foreign Application Priority Data
Jan. 2, 2012 (TW) 101100055

(51) Int. Cl. H01L 33/62

(52) U.S. Cl. 257/88; 257/99; 257/E33.066

(57) ABSTRACT

A solid-state light-emitting package includes a leadframe, a light-emitting chip, and a sealant. The leadframe includes a first electrode and a second electrode. The first electrode has at least one first contact end, and the second electrode has at least one second contact end. The light-emitting chip is electrically connected to the first electrode and the second electrode and is disposed between the first contact end and the second contact end. The sealant covers the leadframe and the light-emitting chip and has a first surface and a second surface. The first surface is the light output surface for the light-emitting chip. The first electrode and the second electrode are bent toward the first surface, where the first contact end and the second contact end are exposed by the first surface.

### BACKGROUND OF THE INVENTION

1. Field of the Invention

The instant disclosure relates to a light-emitting device; in particular, to a solid-state light-emitting device and a solid-state light-emitting package thereof.

2. Description of Related Art

For the existing light-emitting diode (LED) packaging technology, a plastic leaded chip carrier (PLCC) type package structure has been developed. An LED package of such structure not only includes a leadframe, an LED chip, and a sealant, but also includes a plastic cup.

For the PLCC type LED package, the leadframe is combined with the plastic cup, while the LED chip is mounted on the leadframe and is located at the bottom of the plastic cup. The sealant fills the plastic cup completely and covers the LED chip and the leadframe. The plastic cup is formed by molding, such as injection molding, after the leadframe is completed.

Accordingly, in the process for manufacturing the previous LED package, a mold for the plastic cup has to be completed first, so as to form the plastic cup for combining with the leadframe. However, it is necessary to spend much time and money in designing and manufacturing the mold, thereby increasing the production costs.

### SUMMARY OF THE INVENTION

The instant disclosure provides a solid-state light-emitting package, which does not include the plastic cup. Thereby, the molding cost of the plastic cup can be eliminated to reduce the overall manufacturing cost of the LED package.

The instant disclosure also provides a solid-state light-emitting device including a plurality of solid-state light-emitting packages.

The solid-state light-emitting package of the instant disclosure includes a leadframe, a light-emitting chip, and a sealant. The leadframe includes a first electrode and a second electrode. The first electrode has at least one first contact end, while the second electrode has at least one second contact end. The light-emitting chip is electrically connected to the first electrode and the second electrode and is disposed between the first contact end and the second contact end. The light-emitting chip is used for emitting light. The sealant covers the leadframe and the light-emitting chip, where the sealant has a first surface and a second surface opposite to the first surface. The first surface is the light output surface for the light-emitting chip. The first electrode and the second electrode are both bent toward the first surface. The first surface exposes the upper regions of the first contact end and the second contact end.

The instant disclosure further provides solid-state light-emitting device including a plurality of solid-state light-emitting packages.

Based on the above, the solid-state light-emitting package and the device having the same of the instant disclosure utilize the sealant and the leadframe for packaging the light-emitting chip, without using the conventional plastic cup. Therefore, the molding cost of the plastic cup can be saved to reduce the overall manufacturing costs of the solid-state light-emitting package and device having the same.

In order to further appreciate the characteristics and technical contents of the instant disclosure, references are hereunder made to the detailed descriptions and appended drawings in connection with the instant disclosure. However, the appended drawings are merely shown for exemplary purposes, rather than being used to restrict the scope of the instant disclosure.

### BRIEF DESCRIPTION OF THE DRAWINGS

FIG. 1A is a perspective view showing a solid-state light-emitting package for an embodiment of the instant disclosure.

FIG. 1B is a side view of the package shown in FIG. 1A.

FIG. 2A is a perspective view showing a solid-state light-emitting package for another embodiment of the instant disclosure.

FIG. 2B is a side view of the package shown in FIG. 2A.

FIG. 3A is a perspective view showing a solid-state light-emitting package for still another embodiment of the instant disclosure.

FIG. 3B is a side view of the package shown in FIG. 3A.

FIG. 4A is a perspective view showing a solid-state light-emitting device for an embodiment of the instant disclosure.

FIG. 4B is an enlarged view of the section A in FIG. 4A.

FIG. 5 is a perspective view showing a solid-state light-emitting device for another embodiment of the instant disclosure.

### DETAILED DESCRIPTION OF THE EMBODIMENTS

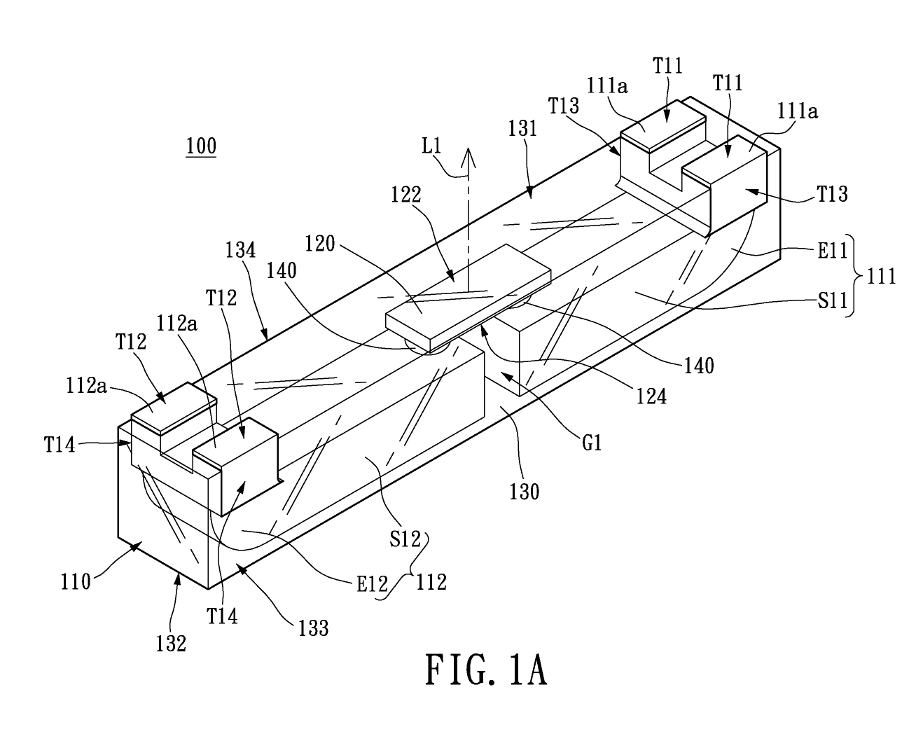

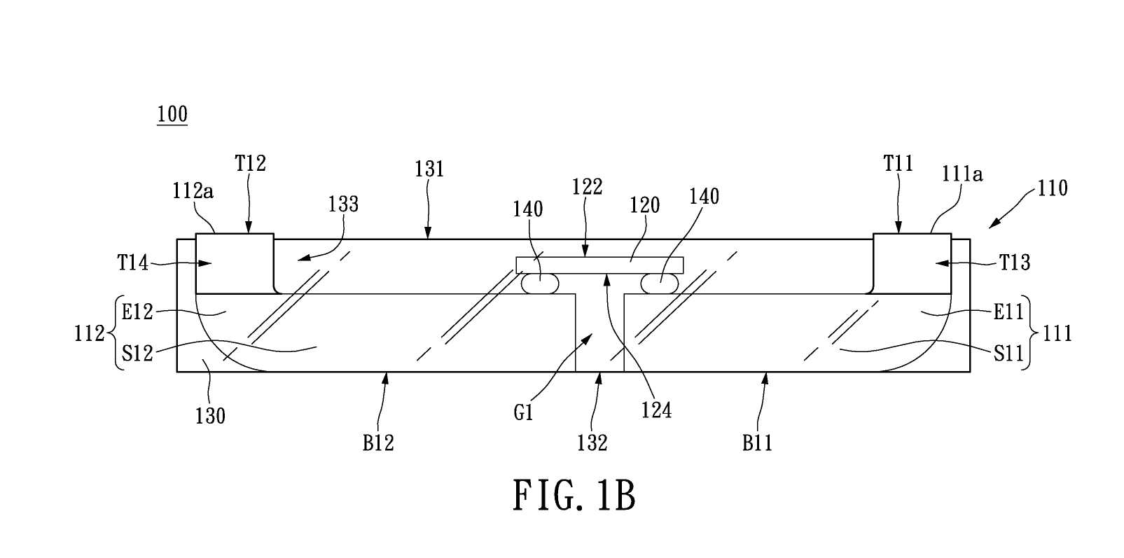

FIG. 1A is a perspective view showing a solid-state light-emitting package 100 for an embodiment of the instant disclosure, while FIG. 1B is a side view of the solid-state light-emitting package 100 in FIG. 1A. Referring to FIGS. 1A and 1B, the solid-state light-emitting package 100 includes a leadframe 110, a light-emitting chip 120, and a sealant 130. The light-emitting chip 120 is mounted on the leadframe 110 and is electrically connected thereto. The sealant 130 covers the leadframe 110 and the light-emitting chip 120.

The leadframe 110 is made of a metallic material, and the leadframe 110 includes a first electrode 111 and a second electrode 112. The first electrode 111 has at least one first contact end 111a, and the second electrode 112 has at least one second contact end 112a. For the embodiment shown in FIG. 1A, the number of the first contact ends 111a is two, and the number of the second contact ends 112a is also two.

However, in another embodiment, the number of the first contact ends 111a that the first electrode 111 has is one or more than two, while the number of the second contact ends 112a that the second electrode 112 has is one or more than two. Therefore, the numbers of the first contact end 111a and the second contact end 112a shown in FIG. 1A are only for illustrative purpose and may be varied.

The sealant 130 has a first surface 131, a second surface 132, a third surface 133, and a fourth surface 134. The first surface 131 is arranged opposite to the second surfaces 132, while the third surface 133 is arranged opposite to the fourth surfaces 134. Moreover, the third surface 133 and the fourth surface 134 are connected between the first surface 131 and the second surface 132. The third surface 133 is connected to the first surface 131 and the second surface 132, while the fourth surface 134 is connected to the first surface 131 and the second surface 132.

The leadframe 110 is partially exposed by the sealant 130. Specifically, as shown in FIGS. 1A and 1B, each first contact end 111a has an upper region T11, and each second contact end 112a has an upper region T12, where the first surface 131 expose the upper regions T11 and the upper regions T12. The first electrode 111 has a lower surface B11, and the second electrode 112 has a lower surface B12, where the second surface 132 exposes the lower surface B11 and lower surface B12. The first electrode 111 further has a pair of opposite lateral regions T13, and the second electrode 112 further has a pair of opposite lateral regions T14. One of the lateral regions T13 and one of the lateral regions T14 on the same plane are exposed by the third surface 133. The other lateral region T13 and the other lateral region T14 on the same plane are exposed by the fourth surface 134.

The upper region T11 of each first contact end 111a and the upper region T12 of the second contact end 112a exposed by the sealant 130 promote heat dissipation. The exposed lower surface B11 of the first electrode 111 and the exposed lower surface B12 of the second electrode 112 are used for connecting to solders (not shown), such as tin solders. Thus, the electric current generated by an exterior electric source can be passed through the solders, the first electrode 111, and the second electrode 112 to the leadframe 110.

Similarly, the lateral region T13 of each first contact end 111a and the lateral region T14 of each second contact end 112a exposed by the third surface 133 and the fourth surfaces 134 can be connected to solders (not shown), such as tin solders. Likewise, electric current generated by an exterior electric source can be passed through the solders, the first contact ends 111a, and the second contact ends 112a to the leadframe 110. Through the exposed lateral regions T13 and T14, the solid-state light-emitting package 100 is usable for a side-edge type light-emitting device, such as a side-edge type backlight module and batten lighting.

In the embodiment, the lower surfaces B11, B12 of the electrodes and the lateral regions T13, T14 of the contact ends are concurrently exposed by the sealant 130. However, concurrent exposure is not required. Based on the specific operational requirement or practical needs, only the lower surfaces B11, B12 or the lateral regions T13, T14 need to be exposed during the manufacturing process.

In addition, the first electrode 111 and the second electrode 112 are bent toward the first surface 131. Specifically, the first electrode 111 includes a first support portion S11 and a first transition portion E11 connected to the first support portion S11. Similarly, the second electrode 112 includes a second support portion S12 and a second transition portion E12 connected to the second support portion S12.

The first transition portion E11 is bent toward the first surface 131 and extends from the first support portion S11 to the first contact ends 111a. Similarly, the second transition portion E12 is bent toward the first surface 131 and extends from the second support portion S12 to the second contact ends 112a. Thus, the first electrode 111 and the second electrode 112 are curved structurally toward the first surface 131. As shown in FIG. 1B, two bent portions of the first electrode 111 and the second electrode 112 respectively are arc-shaped.

The light-emitting chip 120 is electrically connected to the first electrode 111 and the second electrode 112. The light-emitting chip 120 is disposed in between the first contact ends 111a and the second contact ends 112a, where the light-emitting chip 120 may be mounted on the first support portion 511 and the second support portions S12 of the leadframe 110 by a flip chip method. Specifically, the solid-state light-emitting package 100 may further include two solder bumps 140. The solder bumps 140 are disposed between the leadframe 110 and the light-emitting chip 120. The light-emitting chip 120 is connected to the first support portion S11 and the second support portion S12 through the solder bumps 140. Hence, the light-emitting chip 120 is electrically connected to the first electrode 111 and the second electrode 112.

The light-emitting chip 120 may be a light-emitting diode, such as a direct or edge type light-emitting diode. The light-emitting chip 120 is used to emit a light ray L1 and has a light output surface 122 and an opposite lower surface 124. The solder bumps 140 are connected to the lower surface 124.

When the electric current generated by an exterior electric source is passed to the leadframe 110 through the solders, the first contact ends 111a, and the second contact ends 112a, the electric current is transmitted to the light-emitting chip 120 through the solder bumps 140. Thus, the light-emitting chip 120 receives the electric current and emits the light ray L1 from the light output surface 122. In addition, the light ray L1 is emitted from the first surface 131. Thus, the first surface 131 can be a light-emitting surface for the light-emitting chip 120.

Moreover, a space G1 is formed between the first support portion S11 and the second support portions S12, so that the first electrode 111 and the second electrode 112 do not make contact with each other. When the solid-state light-emitting package 100 is in normal use, the first electrode 111 and the second electrode 112 are in electrical communication with one another through the light-emitting chip 120. In other words, if the light-emitting chip 120 in FIGS. 1A and 1B is removed, the first electrode 111 and the second electrode 112 are electrically insulated from one another.

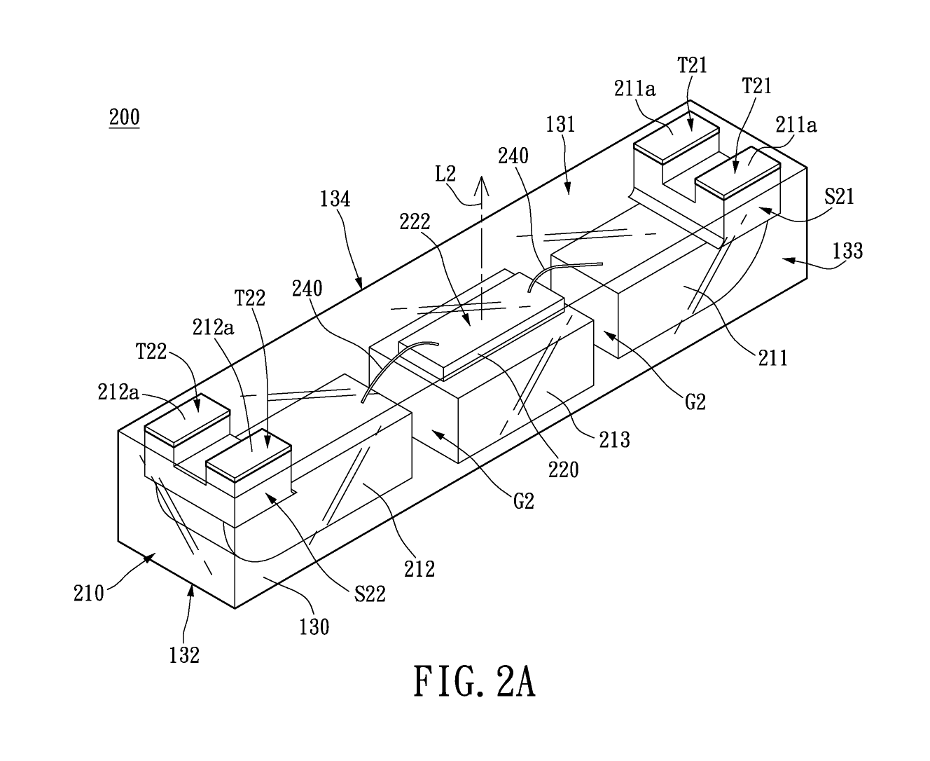

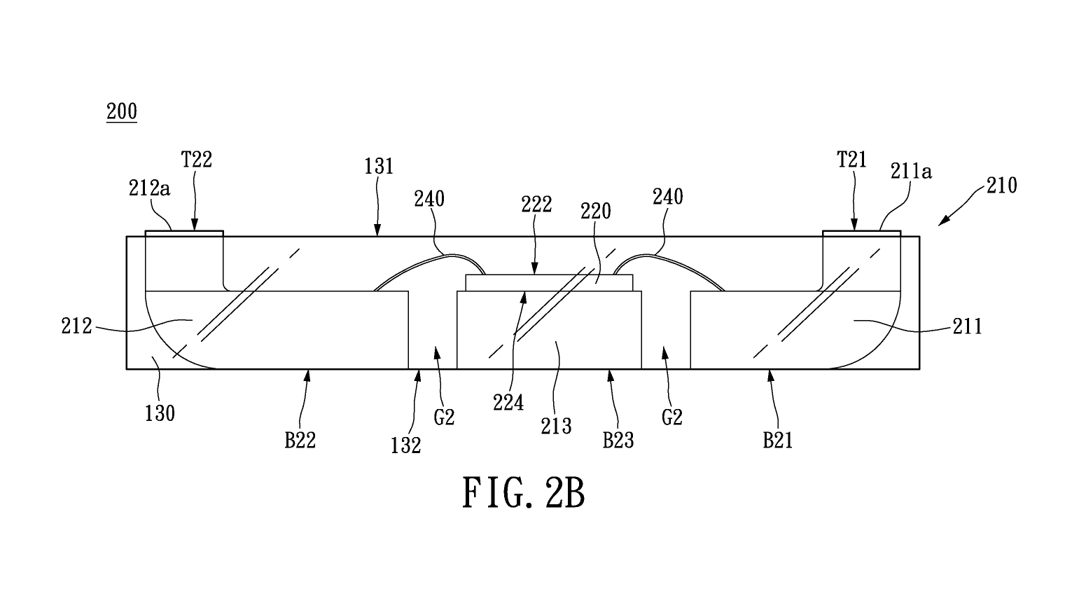

FIG. 2A is a perspective view showing a solid-state light-emitting package 200 for another embodiment of the instant disclosure. FIG. 2B is a side view of the solid-state light-emitting package 200 in FIG. 2A. Referring to FIG. 2A and FIG. 2B, the solid-state light-emitting package 200 includes a leadframe 210, a light-emitting chip 220, and the sealant 130. The light-emitting chip 220 may be a light-emitting diode, such as a direct or edge-type light-emitting diode, where the solid-state light-emitting package 200 has a similar structural configuration as the solid-state light-emitting package 100.

For example, the light-emitting chip 220 is mounted on the leadframe 210. The sealant 130 completely covers the light-emitting chip 220 and partially exposes the leadframe 210. Specifically, an upper region T21 of each first contact end 211a and a upper region T22 of each second contact end 212a are exposed by the first surface 131 of the sealant 130. A lower surface B21 of a first electrode 211 and a lower surface B22 of a second electrode 212 are exposed by the second surface 132 of the sealant 130.

Same as the first electrode 111 and the second electrode 112 of the previous embodiment, the first electrode 211 and the second electrode 212 have bent portions and are bent toward the first surface 131, as shown in FIGS. 2A and 2B. The functions of the first contact end 211a and the second contact end 212a are the same as the functions of the first contact end 211a and the second contact end 212a of the previous embodiment, therefore no further description is provided herein.

However, the solid-state light-emitting package 200 still differs from the solid-state light-emitting package 100. Namely, a wire bonding method is used to mount the light-emitting chip 220 on the leadframe 210. Moreover, the leadframe 210 not only includes the first electrode 211 and the second electrode 212, but further includes a support member 213. In addition, the light-emitting chip 220 may be bonded onto the support member 213 by using adhesives (not shown).

Specifically, the solid-state light-emitting package 200 includes a plurality of bond-wires 240. The bond-wires 240 are cover by the sealant 130, and each of the bond-wires 240 is connected electrically to the light-emitting chip 220 and one of the first electrode 211 and the second electrode 212. Thus, the light-emitting chip 220 is connected electrically to the first electrode 211 and the second electrode 212 through the bond-wires 240. Accordingly, the light-emitting chip 220 receives the electric current from the exterior electric source through the bond-wires 240, the first electrode 211, and the second electrode 212, so that the light-emitting chip 220 can emit a light ray L2.

The light-emitting chip 220 has a light output surface 222 and an opposite lower surface 224. The light-emitting chip 220 emits the light ray L2 from the light output surface 222, and the lower surface 224 is connected to the support member 213 such as by adhesives.

The support member 213 may be disposed in between the first electrode 211 and the second electrode 212. Two spaces G2 are formed. One space G2 is formed between the support member 213 and the first electrode 211. The other space G2 is formed between the support member 213 and the second electrode 212. Thus, the support member 213, the first electrode 211, and the second electrode 212 are spaced apart from each other. Moreover, the support member 213 has a lower surface B23 exposed by the second surface 132, as shown in FIG. 2B. The lower surfaces B21, B22, B23 can be connected to solders (not shown), such as tin solders.

The support member 213, the first electrode 211, and the second electrode 212 are spaced apart from each other, so that the light-emitting chip 220 can receive the electric current through the first electrode 211 and the second electrode 212, and the majority of generated heat by the light-emitting chip 220 is conducted to the support member 213 when the light-emitting chip 220 emits light. Thus, for the solid-state light-emitting package 200, the path for transmitting the electric current is different from the path for conducting most heat.

It is worth noting unlike the previous embodiment, the third surface 133 and the fourth surface 134 of the sealant 130 in FIGS. 2A and 2B do not expose a lateral region S21 of each first contact end 211a and a lateral region S22 of each second contact end 212a. However, in another embodiment, as shown in FIGS. 1A and 1B, the lateral region T13 of each first contact end 111a and the lateral region T14 of each second contact end 112a may be exposed by the third surface 133 and the fourth surface 134 of the sealant 130. In addition, the lateral regions of the support member 213 may be exposed by the third surface 133 and the fourth surface 134 of the sealant 130 for connecting to solders. Therefore, the package 200 shown in FIGS. 2A and 2B are not used to restrict the scope of the instant disclosure.

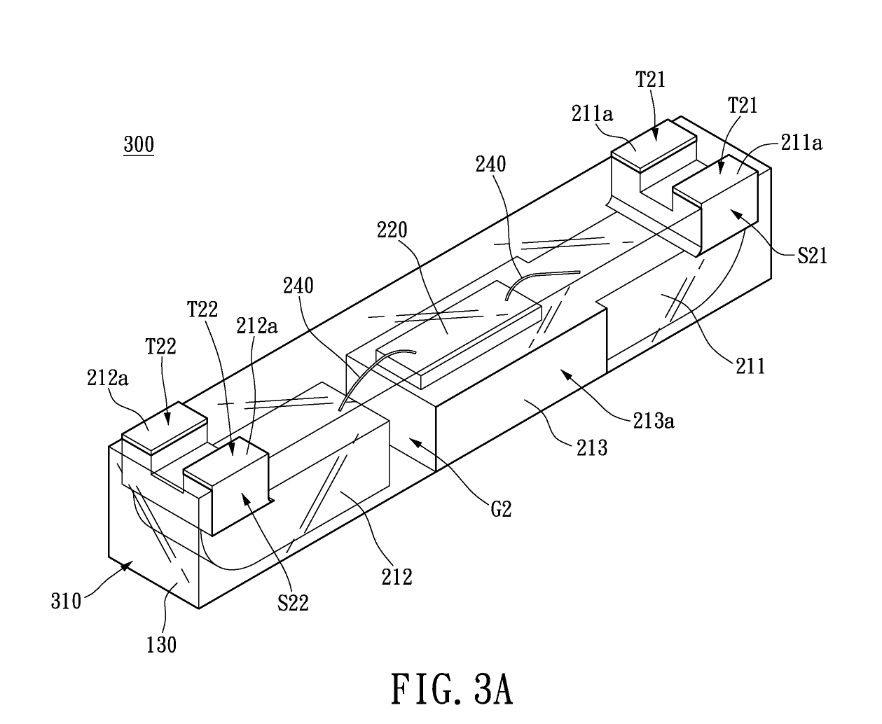

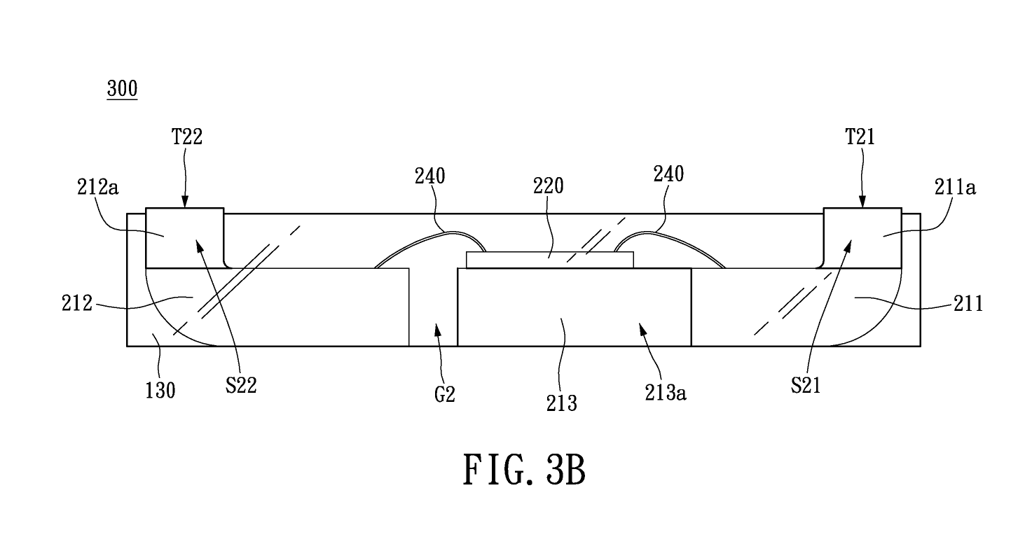

FIG. 3A is a perspective view showing a solid-state light-emitting package 300 for still another embodiment of the instant disclosure. FIG. 3B is a side view of the package 300 in FIG. 3A. Referring to FIGS. 3A and 3B, the package 300 of the embodiment is similar to the package 200 of the previous embodiment. The difference between the package 200 and 300 resides with a leadframe 310 of the package 300.

Specifically, for the leadframe 310, the support member 213 and the first electrode 211 are connected to one another. The support member 213 is only spaced apart from the second electrode 212 with the space G2 formed in between. In other words, when comparing to the package 200, the package 300 of the embodiment has only one space G2.

Since the support member 213 is in connection to the first electrode 211, the light-emitting chip 220 not only receives the electric current from the first electrode 211 but also conducts most heat generated by the light-emitting chip 220 through the support member 213 and the first electrode 211. Thus, for the package 300, the path for transmitting the electric current and the path for conducting most heat overlap one another. Since the package 300 has the same function as the package 200, no further elaboration is provided herein.

In addition, similar to the package 100 in FIG. 1A but unlike the package 200 shown in the FIGS. 2A and 2B, the package 300 shown in FIGS. 3A and 3B has the following characteristics. Namely, the upper region T21 and the lateral region S21 of each first contact end 211a, along with the upper region T22 and the lateral region S22 of each second contact end 212a, are exposed by sealant 130. Moreover, a lateral region 213a of the support member 213 is exposed by the sealant 130, as shown in FIG. 3A.

The exposed lateral regions S21, S22, and the lateral region 213a of the support member 213 can be connected to solders, such as tin solders. Thus, electric current generated by an exterior electric source can be passed to the leadframe 310 through the solders, the first contact ends 211a, and the second contact ends 212a to cause that the light-emitting chip 220 emits light. In addition, the exposed upper regions T21, T22 can promote heat dissipation to reduce the occurrence of overheating in the light-emitting chip 220.

Moreover, the lower surfaces of the first electrode 211, the second electrode 212, and the support member 213 can be exposed by the sealant 130 for connecting to solders.

It is worth noting for another embodiment, based on the operational requirement and practical needs, only the lateral regions S21, S22, 213a need to be exposed during the manufacturing process. For other scenarios, only the lateral regions S21, S22 need to be exposed. Thus, the first contact end 211a and the second contact end 212a shown in FIGS. 3A and 3B are only for illustrative purpose and shall not be used to restrict the scope of the instant disclosure.

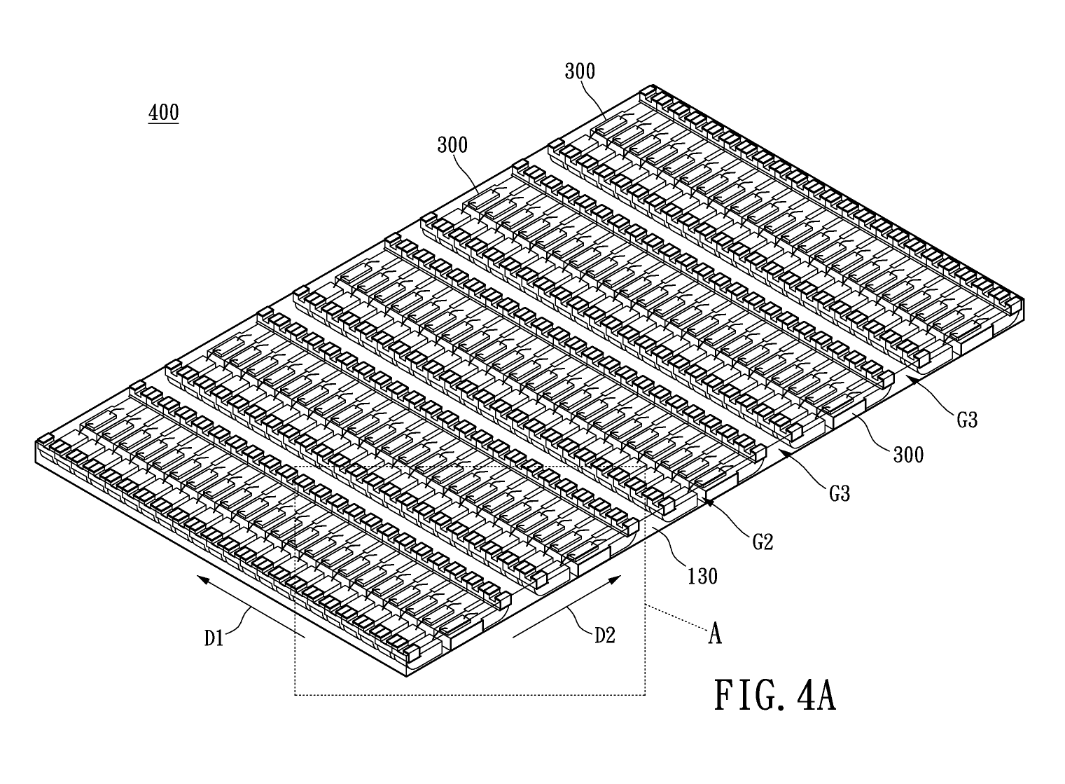

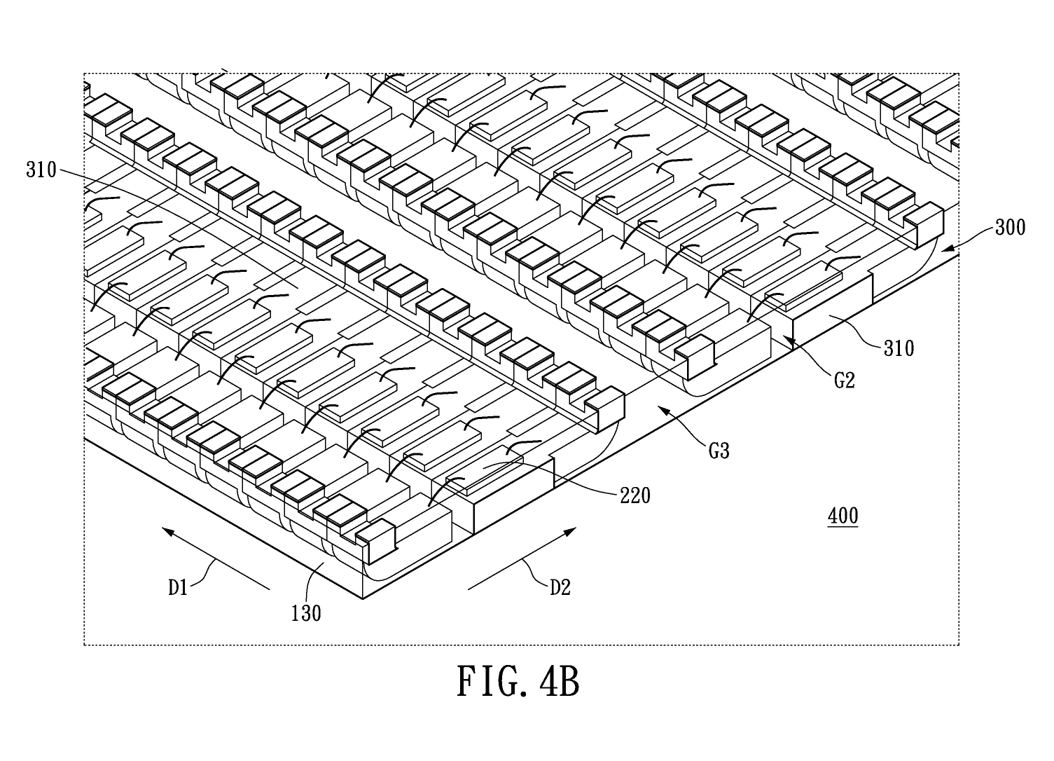

FIG. 4A is a perspective view showing a solid-state light-emitting device 400 for an embodiment of the instant disclosure. FIG. 4B is an enlarged view of the section A in FIG. 4A. Referring to FIG. 4A, the solid-state light-emitting device 400 of the embodiment includes a plurality of solid-state light-emitting packages disclosed by the previous embodiments. For example, the device 400 includes the aforementioned packages 300 (please refer to FIGS. 3A and 3B) in the embodiment as shown in FIGS. 4A and 4B.

However, in another embodiments, the solid-state light-emitting package included by the device 400 may be the solid-state light-emitting package 100 (please refer to FIGS. 1A and 1B) or packages 200 (please refer to FIGS. 2A and 2B). Moreover, the solid-state light-emitting device 400 may include one type or more than one type of solid-state light-emitting package. For example, the solid-state light-emitting device 400 may include solid-state light-emitting packages 200 and 300. Therefore, the solid-state light-emitting device 400 shown in FIGS. 4A and 4b is only for illustrative purpose and shall not be used to restrict the scope of the instant disclosure.

For the embodiment shown in FIGS. 4A and 4B, the solid-state light-emitting packages 300 may be arranged in an array. The solid-state light-emitting packages 300 are arranged along a cross-wise direction D1 adjacent to each other. A space G3 is formed between each adjacent solid-state light-emitting packages 300 along a longitudinal direction D2 of the solid-state light-emitting package 300.

For the solid-state light-emitting device 400, all of the leadframes 310 of the packages 300 can be made by using a metallic plate. In particular, the leadframes 310 can be fabricated by applying a mechanical process to the metallic plate with the use of a stamping press. Thus, the metallic plate can be bent and the spaces G2, G3 can be formed to provide the leadframes 310 shown in FIG. 4B.

After the leadframes 310 have been constructed, the light-emitting chips 220 are mounted thereon. The light-emitting chips 220 can be mounted by the flip chip or the wire bonding method. Then, the sealant 130 is applied to cover the leadframes 310 and the light-emitting chips 220, thereby forming the device 400.

After the solid-state light-emitting device 400 is completed, a dicing process can be applied to the device 400 to separate the individual package 300. In other words, the package 300 shown in FIGS. 3A and 3B can be obtained by dicing the device 400, and each package 300 is a part of the device 400.

For other embodiment, the device 400 may include packages 100 or 200. Therefore, the package 100 shown in FIGS. 1A and 1B and the package 200 shown in FIGS. 2A and 2B can be obtained by dicing the device 400. In other words, the package 100 or 200 is a part of the device 400.

Moreover, the device 400 can be used directly as a light source. For example, the device 400 can be used as a light source for various lighting applications. The device 400 can be combined with a diffuser, a bright enhancement film, and an optical film to make a direct-type backlight module for the liquid crystal display (LCD).

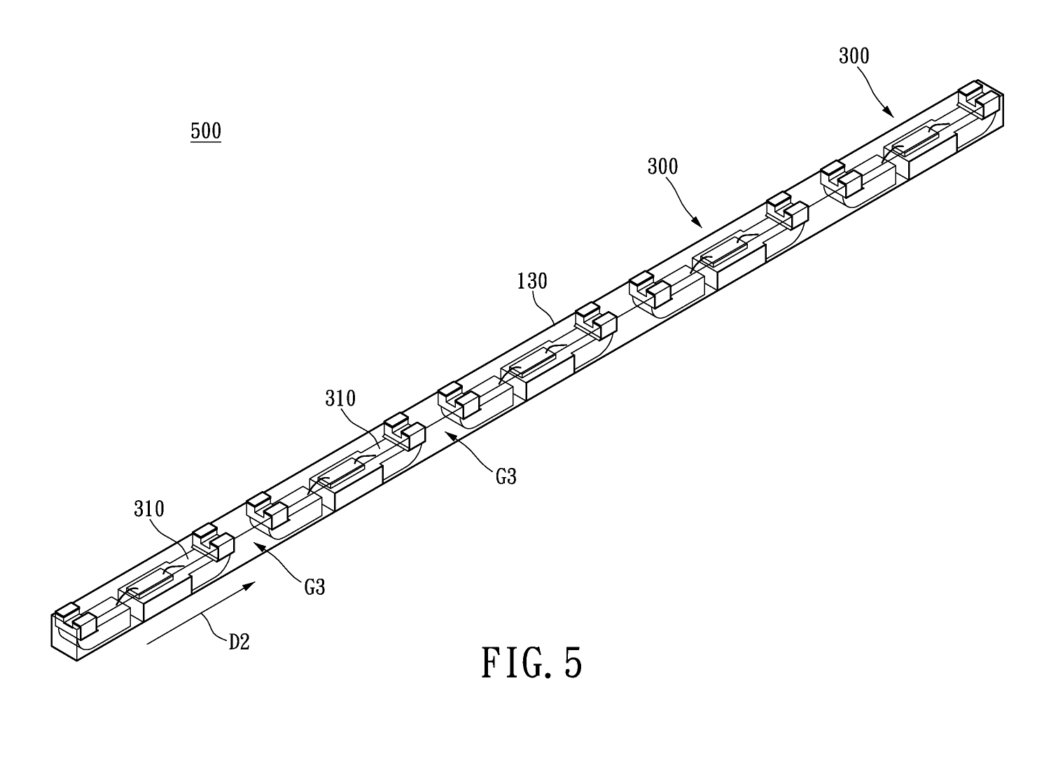

FIG. 5 is a perspective view showing a solid-state light-emitting device 500 for another embodiment of the instant disclosure. Referring to FIG. 5, the solid-state light-emitting device 500 is similar to the device 400 of the previous embodiment. The difference being for the device 500, all of the packages 300 are arranged in a line, where each adjacent leadframe 310 is separated by the space G3.

Specifically, for the device 500, all of the packages 300 are arranged along the longitudinal direction D2 and separated by the space G3 from each other. In addition, the device 500 can be obtained by dicing the device 400. In other words, the device 500 is a part of the device 400.

In addition, the solid-state light-emitting 500 can be used as a light bar. For example, the device 500 can be used as a light source for different lighting applications or used together with the light guide plate (LGP) to make up the side-type backlight module for the LCD.

It is worth noting the packages 100, 200, 300, and the device 500 can be obtained by dicing the device 400 but is not the only way. Even the device 400 itself can be obtained by dicing other device having more packages. Therefore, the abovementioned manufacturing process for the packages 100, 200, 300 and the devices 400, 500 are only for illustrative purpose and shall not be used to restrict the scope of the instant disclosure.

Based on the foregoing, the solid-state light-emitting device and package of the instant disclosure do not have to utilize the plastic cup for packaging the light-emitting chip. Thus, the molding cost for the plastic cup can be saved to reduce the overall manufacturing cost and time of the light-emitting package. In comparing to the existing PLCC type package structure, the solid-state light-emitting device and package of the instant disclosure is more cost effective and has less time for manufacturing.

Moreover, based on the above, the solid-state light-emitting package of the instant disclosure can be obtained by dicing the solid-state light-emitting device. Some solid-state light emitting device (e.g., device 500) can be obtained by dicing another solid-state light emitting device. Thus, by dicing the solid-state light-emitting device (e.g. device 400 of FIG. 4A), different sizes and shapes of solid-state light-emitting devices (e.g., light bar) or solid-state light-emitting packages can be obtained to satisfy the various demands of products.

The descriptions illustrated supra set forth simply the preferred embodiments of the instant disclosure; however, the characteristics of the instant disclosure are by no means restricted thereto. All changes, alternations, or modifications conveniently considered by those skilled in the art are deemed to be encompassed within the scope of the instant disclosure delineated by the following claims.

What is claimed is:

1. A solid-state light-emitting package, comprising:
a leadframe comprising a first electrode and a second electrode, wherein the first electrode has at least one first contact end, and the second electrode has at least one second contact end;
a light-emitting chip electrically connected to the first electrode and the second electrode and disposed between the first contact end and the second contact end, wherein the light-emitting chip is used to emit a light ray; and
a sealant covering the leadframe and the light-emitting chip, wherein the sealant has a first surface and a second surface opposite to the first surface, wherein the first surface is a light output surface for the light-emitting chip, while the first electrode and the second electrode are both bent toward the first surface, wherein the first surface exposes two upper regions of the first contact end and the second contact end.

2. The solid-state light-emitting package of claim 1, wherein the first electrode comprises a first support portion and a first transition portion connected thereto, while the second electrode comprises a second support portion and a second transition portion connected thereto, wherein the first transition portion is bent toward the first surface and extends from the first support portion to the first contact end, while the second transition portion is bent toward the first surface and extends from the second support portion to the second contact end.

3. The solid-state light-emitting package of claim 2, wherein a space is formed between the first support portion and the second support portion.

4. The solid-state light-emitting package of claim 2, wherein the light-emitting chip is mounted on the first support portion and the second support portion by a flip chip method.

5. The solid-state light-emitting package of claim 1, wherein the leadframe further comprises a support member disposed in between the first electrode and the second electrode, and wherein the light-emitting chip is mounted on the support member.

6. The solid-state light-emitting package of claim 5, further comprising a plurality of bond-wires for connecting the light-emitting chip electrically to the first electrode and the second electrode.

7. The solid-state light-emitting package of claim 5, wherein the support member is in connection to the first electrode and a space is formed between the support member and the second electrode.

8. The solid-state light-emitting package of claim 5, wherein one space is formed between the support member and the first electrode, the other space is formed between the support member and the second electrode.

9. The solid-state light-emitting package of claim 5, wherein a lower surface of the support member is exposed by the second surface.

10. The solid-state light-emitting package of claim 1, wherein a lower surface of the first electrode and a lower surface of the second electrode are exposed by the second surface.

11. The solid-state light-emitting package of claim 1, wherein the sealant further has a third surface and a fourth surface opposite to the third surface, while the third surface and the fourth surface are connected between the first surface and the second surface, and the third surface and the fourth surface expose a lateral region of the first contact end and a lateral region of the second contact end.

12. The solid-state light-emitting package of claim 1, wherein two bent portions of the first electrode and the second electrode respectively are arc-shaped.

13. A solid-state light-emitting device, comprising:
a plurality of solid-state light-emitting packages, wherein each of the solid-state light-emitting packages includes:
a leadframe comprising a first electrode and a second electrode, wherein the first electrode has at least one first contact end and the second electrode has at least one second contact end;
a light-emitting chip electrically connected to the first electrode and the second electrode and disposed between the first contact end and the second contact end, wherein the light-emitting chip is used to emit a light ray; and
a sealant covering the leadframe and the light-emitting chip, wherein the sealant has a first surface and a second surface opposite to the first surface, wherein the first surface is a light output surface for the light-emitting chip, wherein the first electrode and the second electrode are both bent toward the first surface, wherein the first surface exposes two upper regions of the first contact end and the second contact end.

14. The solid-state light-emitting device of claim 13, wherein the solid-state light-emitting packages are arranged in a line, and a space is formed between adjacent leadframes.

15. The solid-state light-emitting device of claim 13, wherein the solid-state light-emitting packages are arranged in an array.

16. The solid-state light-emitting device of claim 15, wherein a space is formed between adjacent solid-state light-emitting packages along a longitudinal direction of the solid-state light-emitting package.
